(19) United States
(12) Patent Application Publication
(10) Pub. No.: US 2012/0126310 A1
(43) Pub. Date: May 24, 2012

(54) METHOD FOR FORMING CHANNEL MATERIAL

(75) Inventors: Haizhou Yin, Poughkeepsie, NY (US); Huilong Zhu, Poughkeepsie, NY (US); Zhijiong Luo, Poughkeepsie, NY (US)

(73) Assignee: INSTITUTE OF MICROELECTRONICS, CHINESE ACADEMY OF SCIENCES, Beijing (CN)

(21) Appl. No.: 12/999,380

(22) PCT Filed: Sep. 25, 2010
(86) PCT No.: PCT/CN10/77272

§ 371 Date: Dec. 16, 2010

(30) Foreign Application Priority Data
Mar. 3, 2010 (CN) 201010118194.7

(51) Int. Cl. H01L 29/78; H01L 21/336

(52) U.S. Cl. 257/329; 438/591; 257/E21.409; 257/E29.262

(57) ABSTRACT

The present invention provides a method for forming a channel material, comprising: forming a substrate; forming an MOS device with a dummy gate stack on the substrate; removing the dummy gate stack; forming a channel trench at the channel located under the dummy gate stack; filling the channel trench with the channel material; and forming a gate stack. According to the embodiments of the present invention, the channel material is formed by a replacement gate process after the high temperature process, such as a high temperature annealing, thereby any negative influence on the formed channel material due to the high temperature process may be effectively avoided.

### FIELD OF THE INVENTION

The present invention relates to a technical field of semiconductor design and manufacturing, and particularly, to a method for forming a channel material.

### BACKGROUND OF THE INVENTION

Currently, with the continuous scaling of the feature size of the CMOS device, selection of the channel material becomes more and more important for the CMOS device. The prior art has the disadvantages that most channel materials currently available are not suitable for the high temperature process such as the subsequent annealing, which will seriously affect the performance of the channel material. Therefore, improvement needs to be made thereto.

### SUMMARY OF THE INVENTION

The object of the present invention is to solve at least one of the above technical defects, particularly, the problem that the channel material is affected by the high temperature process such as a subsequent annealing.

In order to achieve the above object, an aspect of the present invention provides a method for forming a channel material, comprising: forming a substrate; forming an MOS device with a dummy gate stack on the substrate; removing the dummy gate stack; forming a channel trench at the channel located under the dummy gate stack; filling the channel trench with the channel material; and forming a gate stack.

In one embodiment of the present invention, the channel material comprises Ge, InGaAs, GaAs, GaN or any combination thereof.

In one embodiment of the present invention, the thickness of the channel trench filled with the channel material is in the range from about 50 Å to about 300 Å, and is preferably 100 Å.

In one embodiment of the present invention, the present method further comprises, when forming the gate stack, forming a threshold voltage adjusting layer by deposition.

The material of the threshold voltage adjusting layer comprises Ta, Al, Ti, TiN, TiAl, TiAlN, TaN or any combination thereof. In one embodiment of the present invention, the thickness of the threshold voltage adjusting layer is in the range from about 3 nm to about 7 nm.

In one embodiment of the present invention, the step of forming the gate stack further comprises: forming one or more gate dielectric layers on the channel trench filled with the channel material; forming the threshold voltage adjusting layer by deposition; and forming a metal gate by deposition. In one embodiment of the present invention, after forming the threshold voltage adjusting layer by deposition, the method further comprises performing a low temperature annealing.

Another aspect of the present invention provides a semiconductor structure, comprising: a substrate; an MOS device with a gate stack formed on the substrate; and a channel trench formed under the gate stack, wherein the channel material filled in the channel trench is formed by a replacement gate process.

In one embodiment of the present invention, the channel material comprises Ge, InGaAs, GaAs, GaN or any combination thereof.

In one embodiment of the present invention, the thickness of the channel trench is in the range from about 50 Å to about 300 Å, and is preferably 100 Å.

In one embodiment of the present invention, the gate stack further comprises at least one threshold voltage adjusting layer.

In one embodiment of the present invention, the material of the threshold voltage adjusting layer comprises Ta, Al, Ti, TiN, TiAl, TiAlN, TaN or any combination thereof.

In one embodiment of the present invention, the thickness of the threshold voltage adjusting layer is in the range from about 3 Å to about 7 nm.

According to the embodiments of the present invention, the channel material is formed by a replacement gate process after the high temperature process such as a high temperature annealing, thereby any negative influence on the formed channel material due to the high temperature process may be effectively avoided.

The additional aspects and advantages of the present invention will be partially described as follows, partially apparent from the following descriptions, or acquired from implementing the present invention.

### BRIEF DESCRIPTION OF THE DRAWINGS

The above and/or additional aspects and advantages of the present invention will be apparent and readily understood in the following descriptions of the embodiments in conjunction with the drawings, in which:

FIGS. 1 to 8 are cross-sectional diagrams of structures resulting from performing intermediate steps of a method for forming a channel material according to the embodiments of the present invention.

### DETAILED DESCRIPTION OF THE EMBODIMENTS

The embodiments of the present invention are described in detail as follows. The examples of the embodiments are illustrated in the drawings, throughout which the same or similar reference signs represent the same or similar elements or elements having the same or similar functions. The embodiments described as follows in reference to the drawings are exemplary and merely used to interpret the present invention, instead of limiting the present invention.

The following disclosure provides many different embodiments or examples to implement different structures of the present invention. In order to simplify the disclosure of the present invention, the components and arrangements of specific examples are described in the following. Apparently, they are just exemplary, and do not intend to limit the present invention. In addition, reference numbers and/or letters can be repeated in different examples of the present invention for the purposes of simplification and clearness, without indicating the relationships between the discussed embodiments and/or arrangements. Further, the present invention provides examples of various specific processes and materials, but a person skilled in the art can realize the availability of other processes and/or usage of other materials. Moreover, a structure described as follows in which a first feature is “on” a second feature, may comprise an embodiment where the first and second features are formed to directly contact with each other, or an embodiment where another feature is formed between the first and second features so that the first and second features may not directly contact with each other.

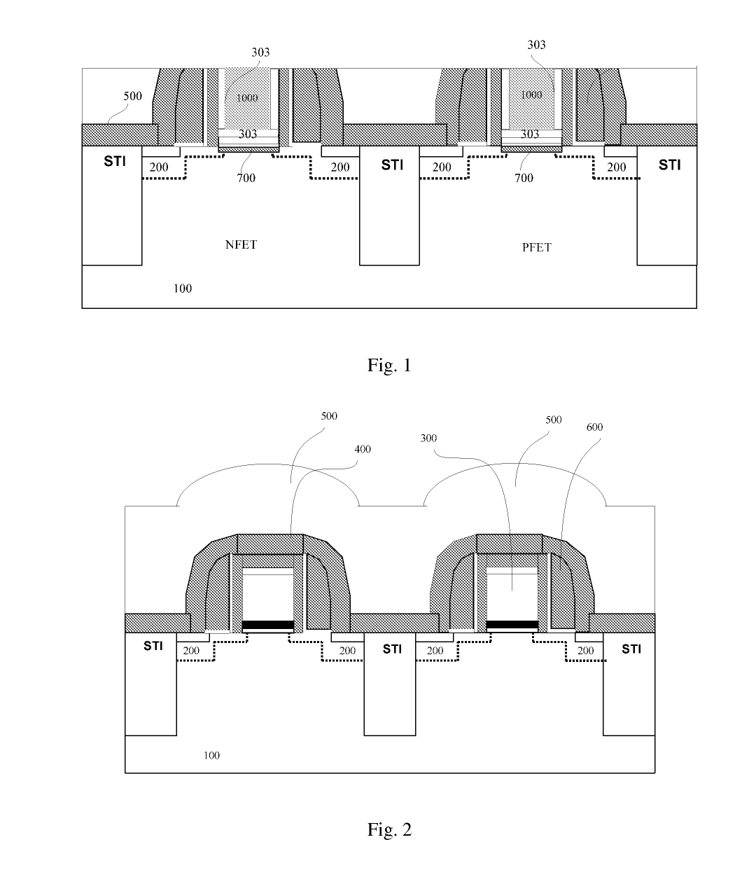

FIG. 1 illustrates a schematic diagram of a semiconductor structure according to an embodiment of the present invention. The semiconductor structure comprises a substrate 100, an MOS device (the CMOS device is taken as an example in the drawing) formed thereon with a gate stack, and a channel trench 700 formed under the gate stack. The channel material filled in the channel trench 700 is formed by a replacement gate process. Therefore, the channel material may be formed by the replacement gate process after the high temperature process such as a high temperature annealing according to the present invention, thereby any negative influence on the formed channel material due to the high temperature process may be effectively avoided.

In order for a better understanding, the present invention further provides a method for forming the above semiconductor structure. FIGS. 1-8 are cross-sectional diagrams of structures resulting from performing intermediate steps of a method for forming a channel material according to the embodiments of the present invention. The method for forming the channel material comprises the following steps:

Step 1: a substrate 100 is formed. In the embodiment of the present invention, the substrate 100 may comprise any semiconductor substrate material, for example, but not limited to, Si, Ge, SiGe, SOI (silicon-on-insulator), SiC, GaAs or any compound semiconductor of the III/V group.

Step 2: a CMOS transistor is formed on the substrate 100 by a conventional CMOS process flow. It is to be noted that although a CMOS structure is described as an example in the embodiment, any other MOSFET is also applicable to the present invention. As illustrated in FIG. 2, the formed CMOS structure comprises a substrate 100, a source/drain (S/D) 200 formed in the substrate 100, a dummy gate stack 300 formed on the substrate 100, spacers 600 formed at both sides of the dummy gate stack 300, a nitride covering layer 400 and a HDP (oxide) 500. In one embodiment of the present invention, the thickness of the nitride covering layer 400 is about 20 nm. In another embodiment of the present invention, the thickness of the HDP 500 is about 300 nm. In an embodiment of the present invention, the dummy gate stack 300 may comprise one or more gate dielectric layers 301, and may also comprise a polycrystalline silicon gate 302 or other layers. The embodiments of the present invention do not have specific limitations to the dummy gate stack 300.

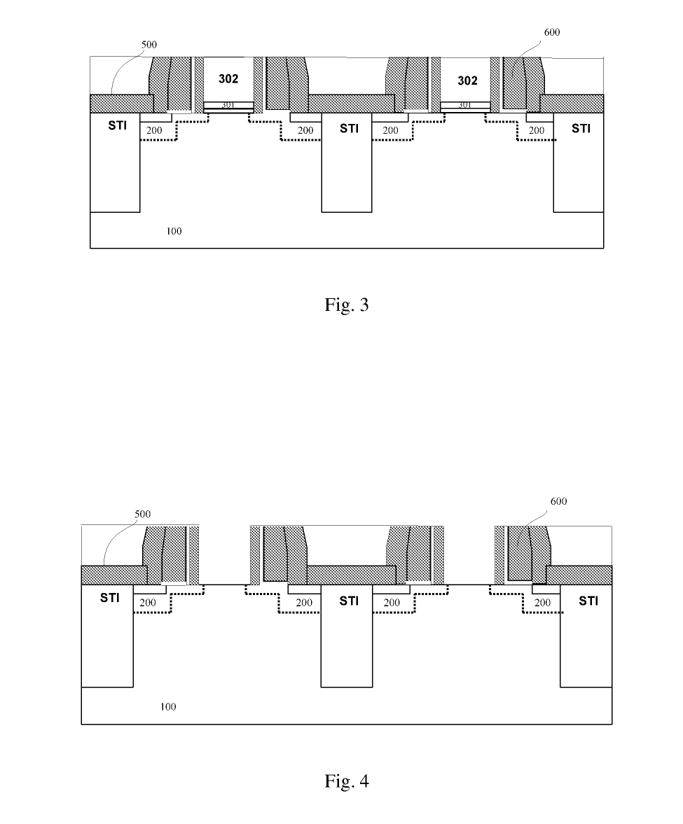

Step 3: a CMP (chemical mechanical polishing) is performed to expose the polycrystalline silicon gate 302, as illustrated in FIG. 3.

Step 4: the polycrystalline silicon gate 302 and one or more gate dielectric layers 301 thereunder are removed (e.g., etched), and the removing step is stopped on the substrate 100, as illustrated in FIG. 4.

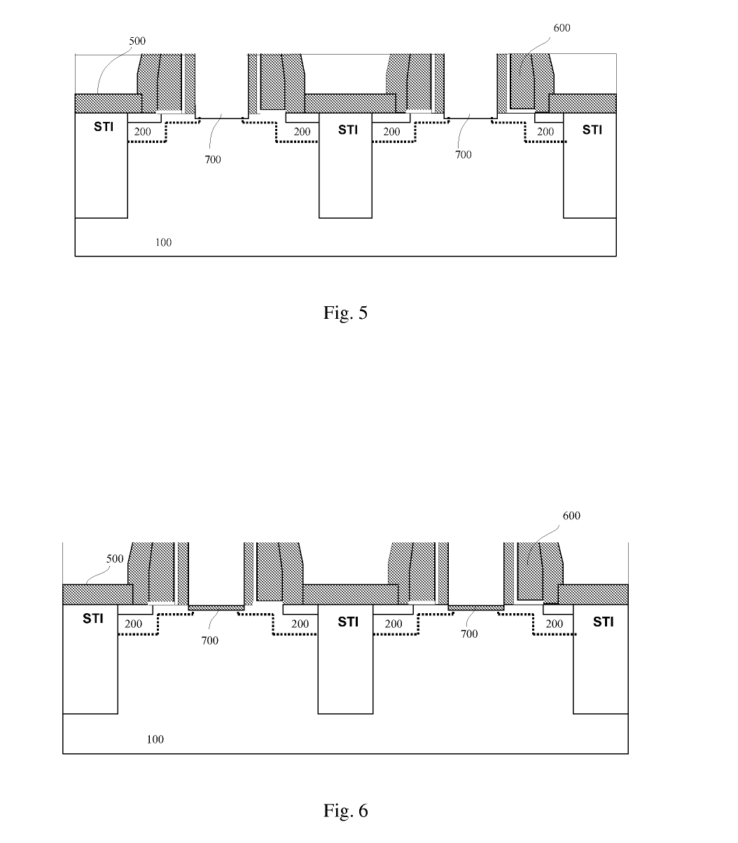

Step 5: a channel trench 700 is formed at the channel located under the polycrystalline silicon gate 302, as illustrated in FIG. 5. In one embodiment of the present invention, preferably the thickness of the channel trench 700 is in the range from about 50 Å to about 300 Å. More preferably, the thickness of the channel trench 700 is 100 Å.

Step 6: a channel material is filled into the channel trench 700, as illustrated in FIG. 6. In one embodiment of the present invention, the channel material may be filled by means of epitaxy growth (Epi). Of course, a person skilled in the art may select other means for filling. In another embodiment of the present invention, the channel material comprises Ge, InGaAs, GaAs, GaN or a combination thereof.

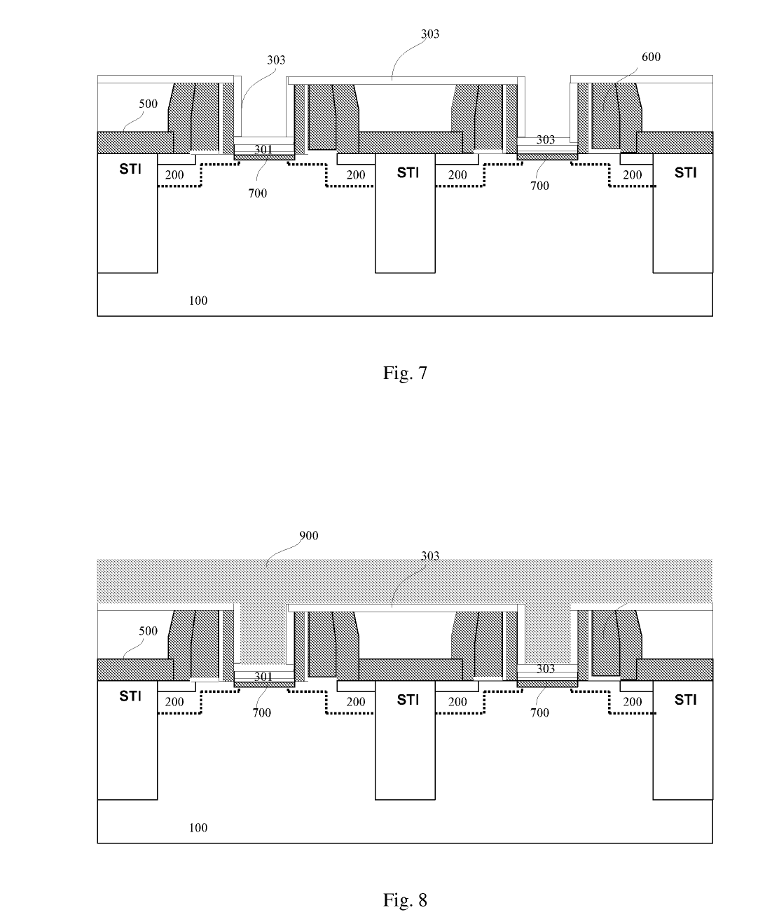

Step 7: a gate stack is formed again. Specifically, one or more gate dielectric layers 301 are deposited, and then a threshold voltage adjusting layer 303 is deposited, as illustrated in FIG. 7. In one embodiment of the present invention, the material of the threshold voltage adjusting layer 303 may comprise Ta, Al, Ti, TiN, TiAl, TiAlN, TaN or any combination thereof. In other embodiments, the thickness of the threshold voltage adjusting layer 303 is in the range from about 3 nm to about 7 nm.

Step 8: a metal gate layer 900 is deposited, as illustrated in FIG. 8.

Step 9: a CMP is performed to remove the metal gate layer 900, and the CMP is stopped on the nitride covering layer 400, so as to form a metal gate 1000, as illustrated in FIG. 1. In one embodiment of the present invention, before performing the CMP in step 9, a low temperature annealing may be performed to the threshold voltage adjusting layer 303. Since the annealing is an low temperature annealing, no negative influence will be generated on the channel material formed in the embodiment of the invention.

The present invention forms the channel material by the replacement gate process after the high temperature process such as a high temperature annealing, thereby any negative influence on the formed channel material due to the high temperature process may be effectively avoided.

Although the embodiments of the present invention have been illustrated and described herein, a person skilled in the art will appreciate that various changes, amendments, substitutions and modifications may be made without deviating from the principle and spirit of the present invention, and the scope of the invention is defined by the accompanied claims and their equivalents.

1. A method for forming a channel material, comprising:
forming a substrate;
forming an MOS device with a dummy gate stack on the substrate;
removing the dummy gate stack;
forming a channel trench at the channel located under the dummy gate stack;
filling the channel trench with the channel material; and
forming a gate stack.

2. The method according to claim 1, wherein the channel material comprises Ge, InGaAs, GaAs, GaN or any combination thereof.

3. The method according to claim 2, wherein the thickness of the channel trench filled with the channel material is in the range from about 50 Å to about 300 Å, and is preferably 100 Å.

4. The method according to claim 1, wherein the step of forming a gate stack further comprising: forming a conductive layer by deposition.

5. The method according to claim 4, wherein the material of the conductive layer comprises Ta, Al, Ti, TiN, TiAl, TiAlN, TaN or any combination thereof.

6. The method according to claim 4, wherein the thickness of the conductive layer is in the range from about 3 nm to about 7 nm.

7. The method according to claim 4, wherein the step of forming a gate stack further comprises:
forming one or more gate dielectric layers on the channel trench filled with the channel material;
forming the conductive layer by deposition; and
forming a metal gate by deposition.

8. The method according to claim 4, after forming the conductive layer by deposition, further comprising: performing a low temperature annealing.

9. A semiconductor structure, comprising:
a substrate;
an MOS device with a gate stack formed on the substrate; and
a channel trench formed under the gate stack, wherein the channel material filled in the channel trench is formed by a replacement gate process.

10. The semiconductor structure according to claim 9, wherein the channel material comprises Ge, InGaAs, GaAs, GaN or any combination thereof.

11. The semiconductor structure according to claim 10, wherein the thickness of the channel trench is in the range from about 50 Å to about 300 Å, and is preferably 100 Å.

12. The semiconductor structure according to claim 9, wherein the gate stack further comprises at least one conductive layer and a gate dielectric layer.

13. The semiconductor structure according to claim 12, wherein the material of the conductive layer comprises Ta, Al, Ti, TiN, TiAl, TiAlN, TaN or any combination thereof.

14. The semiconductor structure according to claim 12, wherein the thickness of the conductive layer is in the range from about 3 nm to about 7 nm.
